(19) United States
(12) Patent Application Publication
(10) Pub. No.: US 2015/0309927 A1
(43) Pub. Date: Oct. 29, 2015

(54) Hybrid Non-Volatile Memory System

(71) Applicant: SanDisk Technologies Inc., Plano, TX (US)

(72) Inventors: Alan Welsh Sinclair, Maddiston (GB); Sergey Anatolievich Gorobets, Edinburgh (GB); Kevin Conley, San Jose, CA (US); Carlos J. Gonzalez, Los Gatos, CA (US)

(21) Appl. No.: 14/738,489

(22) Filed: Jun. 12, 2015

Related U.S. Application Data
(63) Continuation of application No. 13/586,352, filed on Aug. 15, 2012.
Application No. 13/586,352 is a continuation of application No. 12/572,844, filed on Oct. 2, 2009, now abandoned.
Application No. 12/572,844 is a continuation of application No. 10/841,379, filed on May 7, 2004, now abandoned.

(51) Int. Cl. G06F 12/02; G11C 14/00

(52) U.S. Cl. CPC G06F 12/0246; G11C 14/0045; G11C 14/0036; G06F 2212/7201

(57) ABSTRACT

A hybrid non-volatile system uses non-volatile memories based on two or more different non-volatile memory technologies in order to exploit their relative advantages. In an exemplary embodiment, the memory system includes a controller and a flash memory, where the controller has a non-volatile RAM based on an alternate technology such as FeRAM. The flash memory is used for the storage of user data and the non-volatile RAM in the controller is used for system control data. The use of an alternate non-volatile memory technology in the controller allows for a non-volatile copy of the most recent control data to be accessed more quickly as it can be updated on a bit by bit basis. In another exemplary embodiment, the alternate non-volatile memory is used as a cache where data can safely be staged prior to its being written to the memory or read back to the host.

### CROSS-REFERENCE OF RELATED APPLICATIONS

This application is a continuation of U.S. application Ser. No. 13/586,352, filed Aug. 15, 2012, now U.S. Published Application No. 2013/0042057, which is a continuation of U.S. application Ser. No. 12/572,844, filed Oct. 2, 2009, now abandoned, which is a continuation of U.S. application Ser. No. 10/841,379 filed May 7, 2004, now abandoned, and is also related to the following U.S. patent applications: U.S. patent application Ser. No. 10/750,155 filed Dec. 30, 2003, now U.S. Pat. No. 7,139,864; U.S. patent application Ser. No. 10/749,189 filed Dec. 30, 2003, now U.S. Pat. No. 7,433,993; U.S. patent application Ser. No. 10/750,157 filed Dec. 30, 2003, now abandoned; U.S. patent application Ser. No. 10/796,575 filed Mar. 8, 2004, now U.S. Pat. No. 7,173,863; and U.S. patent application Ser. No. 10/841,118 filed May 7, 2004, now abandoned, all of which are hereby incorporated by reference.

### FIELD OF THE INVENTION

This invention relates generally to semiconductor non-volatile data storage systems, and more specifically, to a system incorporating multiple non-volatile memory technologies.

### BACKGROUND OF THE INVENTION

Nonvolatile memory devices such as flash memories are commonly used as mass data storage subsystems. Such nonvolatile memory devices are typically packaged in an enclosed card that is removably connected with a host system, and can also be packaged as the non-removable embedded storage within a host system. In a typical implementation, the subsystem includes one or more non-volatile memory devices and often a subsystem controller.

Current commercial memory card formats include that of the Personal Computer Memory Card International Association (PCMCIA), CompactFlash (CF), MultiMediaCard (MMC), Secure Digital (SD), SmartMedia, xD cards, MemoryStick, and MemoryStick-Pro. One supplier of these cards is SanDisk Corporation, assignee of this application. Host systems with which such cards are used include digital cameras, cellular phones, personal computers, notebook computers, hand held computing devices, audio reproducing devices, and the like.

The nonvolatile memory devices themselves are composed of one or more arrays of nonvolatile storage elements. Each storage element is capable of storing one or more bits of data. One important characteristic of the nonvolatile memory array is that it retains the data programmed therein, even when power is no longer applied to the memory array.

A number of nonvolatile memory technologies exist, have various advantages with respect to one another, and are at various stages of maturity. Perhaps the most common technologies are currently those based on floating gate electrically erasable programmable read only memory (EEPROM) cells, such as the NAND and NOR flash memory technologies. Other technologies include: those based on ferroelectric random-access memory (FeRAM), such as the 1T-1C ferroelectric memory cell; Ovonics Unified Memory (OUM); magnetic RAM (MRAM), such as Giant Magneto-Resistive RAM (GMRAM) (Spin Valve and Pseudo-spin Valve Tunneling), and Magnetoresistive Memory (MJT); Polymer Ferroelectric RAM (PFRAM); Micro Mechanical Memories; Single Electron Memories; Capacitor-less SOI Memories; Nitride Storage Memories; and other technologies being developed.

There are many commercially successful non-volatile solid-state memory devices being used today. These memory devices may be flash EEPROM or may employ some the other types of nonvolatile memory cells. Examples of flash memory and systems and methods of manufacturing them are given in U.S. Pat. Nos. 5,070,032, 5,095,344, 5,315,541, 5,343,063, and 5,661,053, 5,313,421 and 6,222,762. In particular, flash memory devices with NAND string structures are described in U.S. Pat. Nos. 5,570,315, 5,903,495, 6,046,935. Also, nonvolatile memory devices are also manufactured from memory cells with a dielectric layer for storing charge. Instead of the conductive floating gate elements described earlier, a dielectric layer is used. Such memory devices utilizing dielectric storage element have been described by Eitan et al., “NROM: A Novel Localized Trapping, 2-Bit Nonvolatile Memory Cell,” IEEE Electron Device Letters, vol. 21, no. 11, November 2000, pp. 543-545. An ONO dielectric layer extends across the channel between source and drain diffusions. The charge for one data bit is localized in the dielectric layer adjacent to the drain, and the charge for the other data bit is localized in the dielectric layer adjacent to the source. For example, U.S. Pat. Nos. 5,768,192 and 6,011,725 disclose a nonvolatile memory cell having a trapping dielectric sandwiched between two silicon dioxide layers. Multi-state data storage is implemented by separately reading the binary states of the spatially separated charge storage regions within the dielectric.

In flash memory systems, erase operation may take as much as an order of magnitude longer than read and program operations. Thus, it is desirable to have the erase block of substantial size. In this way, the erase time is amortized over a large aggregate of memory cells.

The nature of flash memory predicates that data must be written to an erased memory location. If data of a certain logical address from a host is to be updated, one way is to rewrite the update data in the same physical memory location. That is, the logical to physical address mapping is unchanged. However, this will mean the entire erase block containing that physical location will have to be first erased and then rewritten with the updated data. This method of update is inefficient, as it requires an entire erase block to be erased and rewritten, especially if the data to be updated only occupies a small portion of the erase block. It will also result in a higher frequency of erase recycling of the memory block, which is undesirable in view of the limited endurance of this type of memory device.

Flash memories are a relatively “mature” technology in that it is well understood how to make large memories at a low cost. Flash memories are particularly suited to the storage of large amounts of logically continuous host data; however, as the memory needs to be erased before new data can be written into it, and erase is typically performed on large blocks of cells, this can result in requiring large amounts of overhead, both in data management structures and in some operation times, due to the use of large memory structures that optimize flash memory operations. Some of the other memory technologies can overcome the shortcoming of flash-type memories, but they often have their own relative disadvantages with respect to flash and other alternate technologies.

### SUMMARY OF THE INVENTION

The various aspects of the present invention present a hybrid non-volatile system that uses non-volatile memories based on two or more different non-volatile memory technologies in order to exploit the relative advantages of each technology with respect to the others. In an exemplary embodiment, the memory system includes a controller and a flash memory, where the controller has a non-volatile RAM based on an alternate technology such as FeRAM. The flash memory is used for the storage of user data and the non-volatile RAM in the controller is used for system control data used by the controller to manage the storage of host data in the flash memory. The use of an alternate non-volatile memory technology in the controller allows for a non-volatile copy of the most recent control data to be accessed more quickly as it can be updated on a bit by bit basis. Examples of system control data that can be kept in a non-volatile RAM on the controller include meta-block linking information, status information for the memory blocks, boot information, firmware code, and logical-to-physical conversion data.

In another set of embodiments, the alternate non-volatile memory is used as secure cache where host data can be staged prior to storing in, or reading out, host data in the flash or other memory managed in large erase blocks. This allows for data to be received from the host in one order (as logically continuous sectors) and written into the primary non-volatile memory in another order. Consequently, several semi-autonomous memory arrays can be programmed in parallel without the need to organize the memory into meta-blocks.

Additional aspects, features and advantages of the present invention are included in the following description of exemplary embodiments, which description should be read in conjunction with the accompanying drawings.

### BRIEF DESCRIPTION OF THE DRAWINGS

FIG. 1 is a block diagram showing a memory system connected to a host.

FIGS. 2-4 show various topologies for a hybrid non-volatile memory system.

FIG. 5 shows some examples of different controller uses of such non-volatile RAM.

FIG. 6 is a schematic block diagram of a metablock management system.

FIG. 7 illustrates a hierarchy of the operations performed on control data structures shown in FIG. 6.

FIG. 8 is a schematic block diagram of the metablock management system as implemented in the controller and flash memory in an exemplary embodiment of the present invention.

FIG. 9 is block diagram schematically representing the use of a hybrid non-volatile system according to a non-volatile read/write cache embodiment of the present invention.

FIG. 10 is a schematic representation of the logical to physical mapping of sectors according to an aspect of the present invention.

FIG. 11 a prior art arrangement of the logical to physical mapping of sectors.

FIG. 12 illustrates sequential sector programming using the arrangement of FIG. 10.

FIG. 13 illustrates a data relocation operation using the arrangement of FIG. 10.

FIGS. 14A-14N are a more extensive list of topologies for a hybrid non-volatile memory system.

### DESCRIPTION OF EXEMPLARY EMBODIMENTS OF THE INVENTION

### Hybrid Nonvolatile Memory Systems

The present invention presents nonvolatile memory systems using the various memory technologies. In a principle aspect of the present invention, two different non-volatile memory technologies are used in order to exploit their relative advantages with respect to each other. An exemplary embodiment is a memory system having a controller portion and a memory portion, where the memory portion for the storage of user data is based on a flash EEPROM technology and the controller includes a non-volatile memory from another non-volatile technology, such as FeRAM, for the storage of control and data management information.

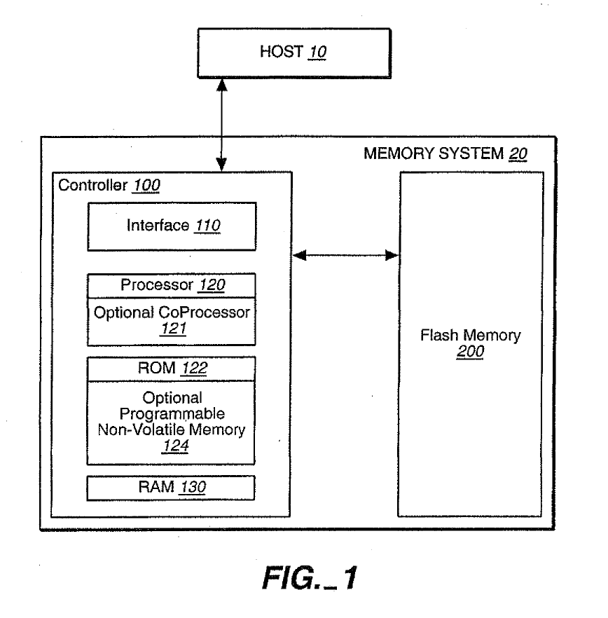

FIG. 1 is a block diagram showing a memory system 20 connected to a host 10. The memory system may be detachable from the host, as in the case of a memory card, or embedded in the host. The memory system 20 includes the non-volatile, here flash, memory 200 for the storage of user data and the controller 100 for the management of the transfer of data between the host 10 and the memory 200 and the storage of the data in the memory 200. The memory 200 is typically made up of one or more separate chips, with the controller 100 formed on another separate chip, although the controller 100 may be formed on the same substrate as the memory 200.

FIG. 1 also shows some of the components commonly found in a controller 100. The controller 100 includes an interface 110, a processor 120, an optional coprocessor 121, ROM 122 (read-only-memory), RAM 130 (random access memory) and optionally programmable nonvolatile memory 124, which is discussed more in the following. The interface 110 has one component interfacing the controller to a host and another component interfacing to the memory 200. Firmware stored in nonvolatile ROM 122 and/or the optional nonvolatile memory 124 provides codes for the processor 120 to implement the functions of the controller 100. Error correction codes may be processed by the processor 120 or the optional coprocessor 121. In an alternative embodiment, the controller 100 is implemented by a state machine (not shown.) In yet another embodiment, the controller 100 is implemented within the host.

Various aspects of controllers are described further in International Patent Publication WO 03/029951 and WO 00/49488 and U.S. patent publications US 2002/0065899 and US 2003/0070036, all of which are hereby incorporated by reference. Various other aspects of non-volatile memories, presented primarily in the flash memory context are presented in U.S. patent application Ser. Nos. 10/750,155 and 10/750,157 and International Patent Publication WO 03/027828, which are hereby incorporated by reference.

RAM memory 130 is a volatile memory and used to store control parameters, file access tables, and other management information. As this information is updated or otherwise changed as the memory operates, it is stored in RAM 130 rather than ROM 122; as a copy of this information is also needed to be maintained non-volatility, a version of this information is keep in memory 200 and then loaded in RAM 130 when the system first started or as needed, with updated copies periodically written back in the memory 200. RAM 130 is also used as a cache for user data transferred between host 10 and memory 200. It is also often preferable to maintain in RAM 130, rather then ROM 122, part or all of the system firmware that has been transferred from memory 200. When firmware is stored in ROM 122, it cannot be changed or updated. By keeping firmware in memory 200, it can be changed if desired; however, this then again requires that the firmware is copied into RAM 130 when the system is first started up so that it may more readily be accessed by the controller as needed.

FIG. 1 shows, in one embodiment of a primary aspect of the present invention, the inclusion of an optional programmable nonvolatile memory 124 as part of the controller. Although any of the various embodiments described here can be implemented for a non-volatile memory system based on only a single technology, the present invention is described mainly in terms of system that uses two or more different technologies in order to exploit the relative advantages of one technology with respect to another. FIG. 1 is one example of a hybrid non-volatile memory system, where the memory 200 is formed of a first solid-state non-volatile memory technology and the programmable nonvolatile memory 124 is formed of second solid-state non-volatile memory technology. According to the specific embodiment, the programmable nonvolatile memory 124 can augment ROM 122 (read-only-memory) and RAM 130 or replace either or both of ROM 122 (read-only-memory) and RAM 130.

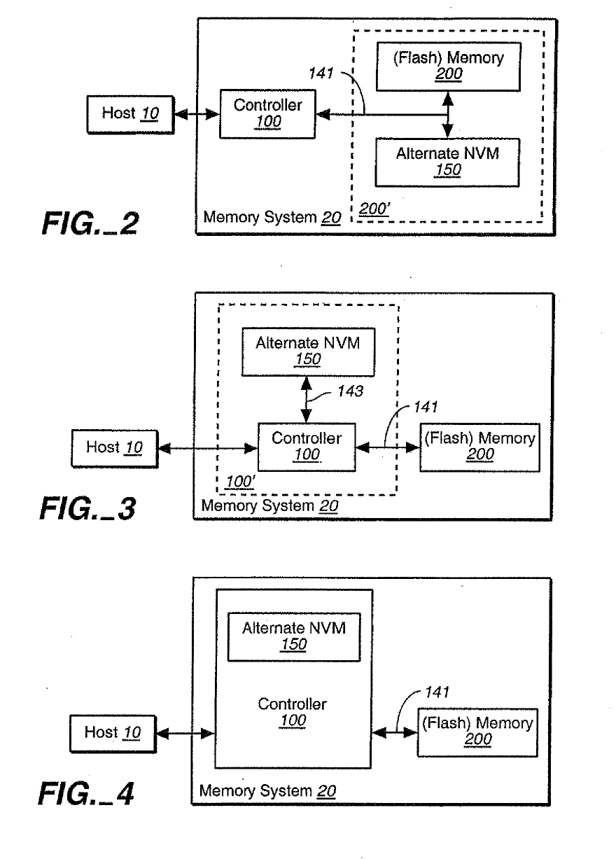

Various topologies for hybrid non-volatile systems are shown in FIGS. 2-4. In any of these arrangements, the benefits to the overall system include “Instant On” capability, faster performance, lower power consumption, and others described in the following.

In both of FIGS. 2 and 3, the host 10 is again connected to memory system 20 that includes controller 100 and memory 200 using a first non-volatile memory technology, which is taken as a Flash memory in the exemplary embodiments. A second non-volatile memory 150 is also included in both cases. In FIG. 2, the alternate non-volatile memory (NVM) 150 uses the same bus 141 as flash memory 200 and may either be on a separate chip or share a chip with one of the flash memory chips forming memory 200. In this arrangement, memory system 20 can be taken to include controller 100 and memory 200′, which in turn includes both memory 200 and alternate non-volatile memory 150, although in the exemplary embodiments discussed below the alternate non-volatile memory 150 is used for system and control data (and, as such, can be taken as part of the controller structure for the system 20) rather than host data. In variation of FIG. 2, both the memory 200 and alternate non-volatile memory 150 are in the same chip, but do not share the same bus 141. They may share the same control state machine on the chip, but the two types of memory are controlled via different protocols and/or commands.

In FIG. 3, the alternate non-volatile memory 150 communicates with the controller 100 through the separate channel of bus 143, rather than using the same bus 141 as flash memory 200. This arrangement avoids the sharing traffic of on a single bus for the two types of non-volatile volatile memory. In this arrangement, controller 100 and alternate non-volatile memory 150 can be taken together as system controller 100′, where in the exemplary embodiments discussed below the alternate non-volatile memory 150 is used for system and control data. When the controller 100 and alternate NVM 150 are on separate chips and are connected by a dedicated bus, the number of pins needed by the controller can be reduced by multiplexing some of the pins for different uses, similar to the arrangement described in U.S. Pat. No. 6,282,130, which is hereby incorporated by reference.

FIG. 4 explicitly shows alternate NVM 150 as part of the controller 100, where the other elements of the controller are suppressed. FIG. 4 can be considered a particular case of FIG. 1, where alternate NVM 150 of FIG. 4 corresponds to the optional programmable nonvolatile memory 124 of FIG. 124. This has been renumbered in FIG. 4 to emphasize that, in the exemplary embodiments, the memory 150 is based on a different non-volatile technology than memory 200; additionally, in the exemplary embodiments the alternate NVM 150 may partially or completely replace one or both of RAM 130 and ROM 122.

A number of other topologies can also be used, either as variations of FIGS. 2-4 or differing significantly. For example, for any of these arrangements, all of the elements of memory system 20, both the controller 100 and memories 150 and 200 can be formed as part of the same chip. For card systems without controllers, such as xD cards or Memory Stick, where the host performs all of the control operations and communicates directly to with the card, the controller 100 would be taken as part of the host system and the card would then consist Memory 200 and alternate NVM 150, either on a single chip or separate chips and communicating with the host with the single bus (141) arrangement of FIG. 2 or the two bus (141, 143) arrangement of FIG. 3.

In an embodiment for card systems with out controllers, the control operations for the memory are moved to the host. The memory system will then consist of the primary memory 200 and the alternate memory 150, where now the host will maintain the management data it will use to transfer data between itself and the primary memory 200. The basic access functions to the primary memory 200 can then be controller by a state machine formed on the same chip as the primary memory.

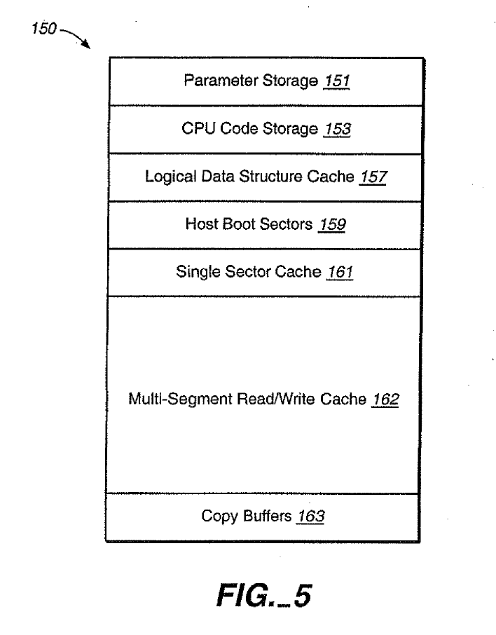

Generally, both the primary non-volatile memory 200 and the alternate non-volatile memory 150 can be formed from any of the various non-volatile technologies both known, such as those described above, and being developed. For example, both of the non-volatile memories could be composed of the same type of non-volatile RAM, replacing even the volatile RAM on the controller; in this case, the entire storage portion of the memory could be modeled on the cache structure described below with respect to FIG. 5. Most of the following, however, will focus on using two different types of non-volatile memory, using a flash memory as the exemplary embodiment for the primary non-volatile memory 200. This is mainly as the focus in the following is on the alternate non-volatile memory 150, and due to flash EEPROM memories being a common technology for the primary non-volatile memory 200. The following discussion readily extends to cases where the memory 200 uses other forms of non-volatile memory with characteristics (for a given application) that are superior to flash and would allow elimination of flash, e.g. a non-volatile memory with the ability to program or erase more data at a time.

Although any of the various embodiments presented herein could be implemented using only a single one of various non-volatile memory technologies, one of the principle aspects of the present invention uses more than one of these technologies in order to exploit their relative advantages with respect to each other. For example, flash EEPROM memories are a well-developed, “mature” technology, having advantages such as having high densities and relatively low costs that are well adapted for bulk storage of logically continuous host data. Consequently, the exemplary embodiments of the present invention will use a flash EEPROM memory with, for example, a NAND architecture using a large block structure for memory 200. (For similar reasons, a set of variations on the present invention can be based on a disc storage system for the memory 200.) The alternate non-volatile memory 150 will use one of the other technologies that has a finer erase or write granularity, faster access speed, differing reprogramming abilities (such as being programmed without first being erased), and/or other relative advantages with respect to memory 200. Particular examples described below will use the alternate NVM 150 as a faster non-volatile cache or for control/system data erasable at the bit or byte level. Examples include FeRAM), MRAM, or even non-flash EEPROM that is bit- or byte-wise erasable.

### Non-Volatile Cache Structures

As a particular example, consider the case where host data is stored in flash memory 200, and alternate NVM 150 is used as a cache-type structure to replace many or all of the functions of RAM 130 and ROM 122 using one of the arrangements of FIGS. 2-4. (Various aspects of cache usage in non-volatile memory systems are described further in U.S. patent application Ser. No. 10/796,575, incorporated by reference above.) When there is need to refer to specific arrangement, that of FIG. 4 with alternate NVM based upon the FeRAM is used. FIG. 5 shows some examples of different controller uses of such non-volatile RAM.

As noted above, flash memory based storage system has some problems that are similar to a disk storage system and can benefit from an alternate NVM with a comparative advantage such as faster random access or finer erase granularity. For example, flash memory can suffer latencies due to its large block architecture. Such latencies occur due to the need to move data around to keep it valid when these blocks need to be erased but still contain valid data. A non-volatile cache could allow host operations to continue without having to wait for the flash operation to complete.

In some cases, such caching can help avoid accessing the flash at all. In such cases, not only is the performance of the system increased, but also the overall lifetime of the system is extended. This is a result of reduced program and erase cycling in the flash memory 200 that is the primary limiter of flash lifetime.

The large-block nature of flash memory also requires the storage system to maintain sophisticated block management and address translation data structures and algorithms. Such sophistication is necessary to optimize performance in systems that still access flash storage systems using a sector size (512 bytes) that is relatively small compared with the effective erase block sizes (currently in the rage 16 kB to 512 kB). The benefit of an alternate NVM in the system would be twofold. First, performance could be increased by removing the need to access flash memory each time the data structures were needed or were update, and second, some of the sophistication could be reduced due to the performance enhancement of the cache behavior. It is reasonable to expect that with a reduction in the sensitivity to block size, that the block size could be increased, further reducing the cost of the flash memory and the storage system as a whole.

When memory 200 uses multi-level cells (MLC), program and erase operations are even longer than for binary memories, making them more susceptible to problems resulting from power loss and reducing performance. If this reliability and performance gap can be bridged, the MLC can address those markets previously only addressable with Binary memory. This provides significant cost benefits that can more than compensate for the added cost of a hybrid non-volatile memory system.

The storage of defective block information would be convenient even if only small amounts of fast access NVM memory were available. Another application would be the storage of hot (or experience) count information for physical blocks. This would be an improvement in both performance and reliability since no additional program time would be required during erase to program the hot count back and the window in which such a count could be lost would not exist.

Returning to FIG. 5, an exemplary embodiment includes Parameter Storage 151, CPU Code Storage 153, Logical Data Structure Storage 157, Host Boot Sectors 159, Single-Sector Cache 161, Multi-Segment Read/Write Cache 162, and Copy Buffers 163. The alternate NVM 150 can store all the parameters that govern configuration and operation of the flash storage system 20 in Parameter Storage 151. Configuration parameters include parameters that govern information reported to the host, information about particular components (e.g. memory type), assembly information (e.g. number of components, presence of regulator or external chip decode circuitry), operating voltage, etc. Operating parameters include those that govern performance, power consumption, etc.

The alternate NVM 150 can store the entire code set for the CPU at CPU Code Storage 153. The CPU of a system needs a location from which its program can be executed. Typically, the program is contained in either a ROM or EEPROM and is loaded from the main storage media into RAM, or is some combination of these approaches. If sufficient alternate NVM 150 is available, it can be used to hold the program in place of these other memories. In addition to the CPU program storage, the CPU needs memory to store temporary variables, card data structures and parameters that govern product operation or configuration and these can also be kept at 153, which previously would be kept in a “Scratch Pad” area of RAM 130. Consequently, Blocks used to store operating programs and product parameters would no longer be necessary since this information could be stored in the alternate NVM 150.

The card can cache the logical translation data structures in Logical Data Structure Storage 157. This could include sector address tables (SATs), group access tables (GATs), and other such structures for logical-to-physical address conversions, such as those described in U.S. patent application Ser. No. 10/750,155, which was incorporated by reference above.

Host Boot Sectors 159 contain logical sectors that are frequently read or updated during host boot times to provide “Instant On” functionality. If the policies for maintaining these addresses in the cache do not differ significantly, this section may just be an extension of the multi-segment read/write cache.

Single-Sector Cache 161 is used to capture frequently written single-sector operations in order to avoid causing garbage collections on the flash. For example, directory, Inode, or FAT addresses other than those for host boot operations could be cached in this section. This section may or may not just be an extension of the multi-segment read/write cache.

Multi-Segment Read/Write Cache 162 can be used for sequential read and write operations from the host. Segments can be adaptive and be split or joined as necessary to reduce flash memory access. If NVM 150 is large enough, it could be used as the data cache buffer of the controller instead of the usual DRAM or SRAM based RAM. A preferred way to serve in this capacity would be for the controller 10 to use the memory 150 as a multi-segmented cache. In such a capacity, the memory can be divided up into multiple segments, each of which functions as an independent cache memory. Typically the number of segments varies according to the needs of the host system. Segments may be split or merged depending on host operation. Each segment can operate independently, each with its own size, cache policy and logical address range. All these parameters can also be adaptive to optimize the host performance. Typical cache policies include read-cache, where data is sent to the host without accessing main media. Read caches can also be enhanced by adding read-behind, read-ahead or read-on-arrival techniques. Other policies are related to write operations. Write-cache policies include write-through (where data is passed to the main storage media as soon as possible) and write-back (where data is passed to the main storage media only when necessary) policies. Write-cache boundaries are typically adjusted by splitting segments or concatenating separate segments.

The last section explicitly shown in FIG. 5 is the Copy Buffers 163. This section is for handling data copy operations that may be necessary during error recovery or garbage collection operations.

If all the techniques shown in FIG. 5 are implemented on a hybrid non-volatile memory storage system, there is a good opportunity to remove from the system some of the special flash blocks that are typically kept in the flash memory 200. This results in an increase in the number of blocks usable for user data that will ultimately extend the reliability of the product.

In addition to what is explicitly shown in FIG. 5, other data maintained in the alternate non-volatile memory 150 could include that from the chaotic blocks, security blocks, and system usage blocks. In previous usage, the chaotic block will hold single, random-address sector writes. (The usage of chaotic blocks is described further in U.S. patent application Ser. No. 10/750,155.) Such blocks are garbage collected on occasion which can cause long latencies. This is especially true since these blocks do not keep their sectors aligned to memory planes. By keeping all such data specifically in a separate NVM, the overall performance of the system is increased. If blocks containing security information are read or updated frequently, it may be valuable to store this data rather in a fast access NVM. With respect to system usage blocks, if the memory 150 is large enough, all system index information could be kept in the NVM, as discussed above with respect to a “Scratch Pad” RAM section. Such usage would increase performance and reliability.

The arrangement of FIG. 5 has a number of advantages. There is a gain in data reliability by including Multi-Segment Read/Write Cache buffer 162 in the alternate NVM 150 over using volatile RAM 130 as a buffer since data does not have to be flushed to flash memory or disk in order to be safe during power down. The reason for this is that flash operations for storing data are typically hundreds of microseconds and access time on disks can be multiple milliseconds. Such operations can be interrupted due to power loss leaving data in an unwritten or unreliable state. If the buffer is constructed of NVM, there would still be a reliable copy of the data that could be used in such cases, increasing the reliability of the overall system.

Some parameters and data structures for a storage system need to be updated periodically. In flash memory or disk based storage systems, the storage takes time and provides an opportunity for corruption in the event of a power loss. Using a fast access NVM increases system reliability, as no access to the media is necessary, thus removing the opportunity for corruption of parameters or data structures. Atomic program operations could be designed using the NVM 150 to hold semaphores for program operations. These could also indicate if data were valid or not.

If the cache-hit ratio is sufficiently high, access to the lower bandwidth main media in memory 200 is reduced. The cache-hit ratio is a function of the cache memory size and the effectiveness of the cache-segmenting algorithm to address the needs of the host activity. By reducing the contribution of the low-bandwidth bus and utilizing the higher bandwidth of the cache memory, the overall performance of the entire system is increased by introducing Multi-Segment Read/Write Cache 162 into the alternate NVM 150.

In systems that upload code from the main storage media 200 into a RAM 130, it is typical that only a portion of the code is contained in the memory at any given time. It is therefore necessary for the system to “page” portions of the program, called “overlays”, from the main media into the RAM 130. This paging operation can cause a latency that reduces overall system performance. If alternate NVM 150 is large enough that the entire program can be held, this can remove the need to page overlays, thus improving the system performance.

Similarly, the controller's CPU often needs memory to store temporary variables, card data structures and parameters that govern product operation or configuration. In systems that rely on data structures that are at least partially stored in the main media of memory 200, accesses to the media can be reduced by storing them in Parameter Storage 151. By reducing the access to the main media, overall system performance is improved similar to the program overlay paging discussed earlier.

Another set of advantages that follow from the use of a alternate non-volatile memory 150 as part of the controller is that it provides “instant on” capability. Some information that the host system will need upon power-up can be cached in alternate NVM 150 and available upon card power-on. Determination of the location of such information can easily be determined either deterministically through knowledge of the host system or by monitoring host activity. Being able to supply such data to a host without the need to access the main media of the storage system allows the overall system to boot quickly. This “Instant On” capability is becoming more important as a necessary capability of personal computing systems. Additionally, by avoiding the need to access the main media in memory 200 to upload the CPU firmware program, the storage system can respond to the host faster providing even further reduction in the overall startup time of the host system.

### Control Data Example

This section develops a particular exemplary embodiment based on FIG. 4 where the flash memory 200 is used for the storage of host data and the alternate non-volatile memory 150 is used by the controller to store various system control data. By using the alternate NVM 150 in this way, this information can be kept non-volatilely without having to maintain a copy in the flash memory 200. This saves having to copy the information from flash memory 200 at power up and avoids having to update the copy maintained in the flash memory, with the various complications that this causes due to having to update only a few bits of information stored in a memory based on large block structures. Keeping system control information in fast non-volatile memory 150, based for example on FeRAM or MRAM technology, allows the most recent version of the control data to be rapidly accessed and updated on a bit- or byte-wise level in non-volatile memory, thereby increasing operating speeds and data reliability and reducing data management complexities.

Specific examples system control data to be stored in non-volatile RAM 150 include:

Logical to physical or meta-block (virtual) address tables, such as sector access tables (SATs) or group access tables (GATs);

Erase block information (e.g. erase pool map or list);

Memory system configuration information;

Meta-block linking information, bad block and spare block information;

Map of bad/weak flash memory bits/bytes/areas. This information can be used to implement system level physical cell substitution;

Hot counts for the metablocks or/and physical blocks (especially if dynamic block linking is used);

Hot counts for the logical sectors/clusters/groups. This information can be used to detect logical ‘hot areas’ that are frequently accessed;

History of host accesses, typical host access sequences. This information can be used to optimize the work of various host data cache techniques or/and data allocation techniques (chaotic block rules) in the memory system;

Information about pending operations, such as garbage collection;

Flags indicating start and end/status of flash page operations (read, write, erase, copy), complex control operations such as garbage collection, control update, error handling, block re-linking etc.;

Logical Block Address (LBA) re-mapping information, if the system uses the information from file access tables (FAT) about logical block linking into files and physically defragments logically fragmented files; and/or

Other control data, so that non-volatile RAM 150 acts as a scratch pad memory.

Many of these structures are described in more details in U.S. patent application Ser. Nos. 10/750,155 and 10/750,157 and International Patent Publication WO 03/027828, which are incorporated by reference above.

On the storage of logical block addresses, in one embodiment, the alternate non-volatile memory can be used to store a dedicated range of LBAs, a range of LBAs predefined by the host, or a range of LBAs accessed by a special command. As an example, there are digital cameras that use part of the memory card's space for common use, like external SRAM. Such an application would benefit from using the second non-volatile RAM of memory 150.

Other data that can be stored in the alternate non-volatile memory is various host data. This can include data access security rules, keys, passwords and licenses and user Ids and passwords. Other such host data includes raw data, say from sensors of ADCs, for the subsequent processing of photo image data or audio/video streams, e.g. JPEG or MPEG transformation, by the system's run program. A further example is user data for the following compression, where all the data gets compressed before it is written to flash memory. In this case, the logical capacity (free space) of the memory may increase.

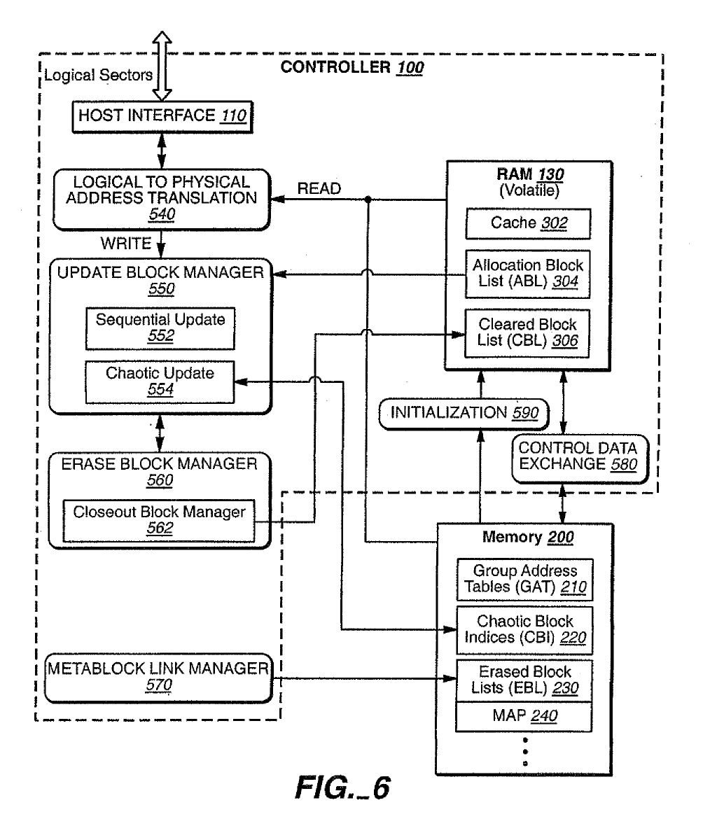

A concrete example of such an embodiment will be based on the control structures described in U.S. patent application Ser. No. 10/750,155, particularly the description related to FIGS. 6 and 20 therein, and a similar structure described in International Patent Publication WO 03/027828, particularly the description related to FIG. 6 therein. These present a hierarchy of control data for the management of data structures based on the relative frequency with which the copies maintained in the flash memory for various structures are updated. Much of this data relates to the status and linking of the physical structures, where details on linking are developed in U.S. patent application Ser. No. 10/750,157.

As described in these applications, the memory system needs to keep various control data used by the controller in a way that will not be lost when the system is shut down. Since the information may be updated (as with pointers or lists) or may need to be changed (as with firmware), the controller cannot keep this material in ROM 122. In previous arrangements, such as these applications, a copy is kept in flash memory and then the control data (or a pointer to it) is loaded into a cache in the controller's RAM 130. At power up, the flash memory can be scanned to assemble some of this information, but it is usual to update this information every so often to reduce the amount of scanning and cut down on initialization times. According to the present invention, if the controller contains a non-volatile RAM, the most recent version can be securely kept in the controller, resulting in instant on capability and always having the latest version saved in a non-volatile memory.

FIG. 6 (which is adapted from U.S. patent application Ser. No. 10/750,155, where it is developed further) is a schematic block diagram of the metablock management system as previously implemented in the controller and flash memory. The metablock management system comprises various functional modules implemented in the controller 100 and maintains various control data (including directory data) in tables and lists hierarchically distributed in the flash memory 200 and the controller RAM 130. The function modules implemented in the controller 100 includes an interface module 110, a logical-to-physical address translation module 540, an update block manager module 550, an erase block manager module 560 and a metablock link manager 570. (Although discussed here in terms of metablocks, the discussion also extends to other logical structures used to increase parallelism, such as could be used for the parallel programming of sectors with a page in a single erase block.)

The interface 110 allows the metablock management system to interface with a host system. The logical to physical address translation module 540 maps the logical address from the host to a physical memory location. The update block Manager module 550 manages data update operations in memory for a given logical group of data. The erased block manager 560 manages the erase operation of the metablocks and their allocation for storage of new information. A metablock link manager 570 manages the linking of subgroups of minimum erasable blocks of sectors to constitute a given metablock. More detailed description of these modules is given in U.S. patent application Ser. No. 10/750,155.

In addition to the sort of metablock management described in the exemplary embodiment, U.S. patent application Ser. No. 10/750,155 also describes a process that scans the block-based primary memory and builds linking tables in that are managed by the controller in SRAM. According to an alternate embodiment of the present invention, the entire logical-to-physical table and update structures, as described therein, can be stored and maintained in NVRAM 150.

During operation the metablock management system generates and works with control data such as addresses, control and status information. Since much of the control data tends to be frequently changing data of small size, it cannot be readily stored and maintained efficiently in a flash memory with a large block structure. To compensate for this, the cited references use a hierarchical and distributed scheme to store the more static control data in the nonvolatile flash memory 200 while locating the smaller amount of the more varying control data in volatile controller RAM 130 for more efficient update and access. In the event of a power shutdown or failure, in this scheme the control data in the volatile controller RAM needs to be rebuilt from control data in the nonvolatile memory. In addition, some of the control data that requires persistence are stored in a nonvolatile metablock that can be updated sector-by-sector, with each update resulting in a new sector being recorded that supercedes a previous one. A sector-indexing scheme is employed for control data to keep track of the sector-by-sector updates in a metablock.

In the arrangement of FIG. 6, the non-volatile flash memory 200 stores the bulk of control data that are relatively static. This includes group address tables (GAT) 210, chaotic block indices (CBI) 220, erased block lists (EBL) 230 and MAP 240. The GAT 210 keeps track of the mapping between logical groups of sectors and their corresponding metablocks. The mappings do not change except for those undergoing updates. The CBI 220 keeps track of the mapping of logically non-sequential sectors during an update. The EBL 230 keeps track of the pool of metablocks that have been erased. MAP 240 is a bitmap showing the erase status of all metablocks in the flash memory. The volatile controller RAM 130 stores a small portion of control data that are frequently changing and accessed; although this copy of the control data will be current, as RAM 130 is volatile it will be lost in a power shutdown or failure. This includes an allocation block list (ABL) 304 and a cleared block list (CBL) 306. The ABL 304 keeps track of the allocation of metablocks for recording update data while the CBL 306 keeps track of metablocks that have been de-allocated and erased. In this embodiment, the RAM 130 acts as a cache for control data stored in flash memory 200.

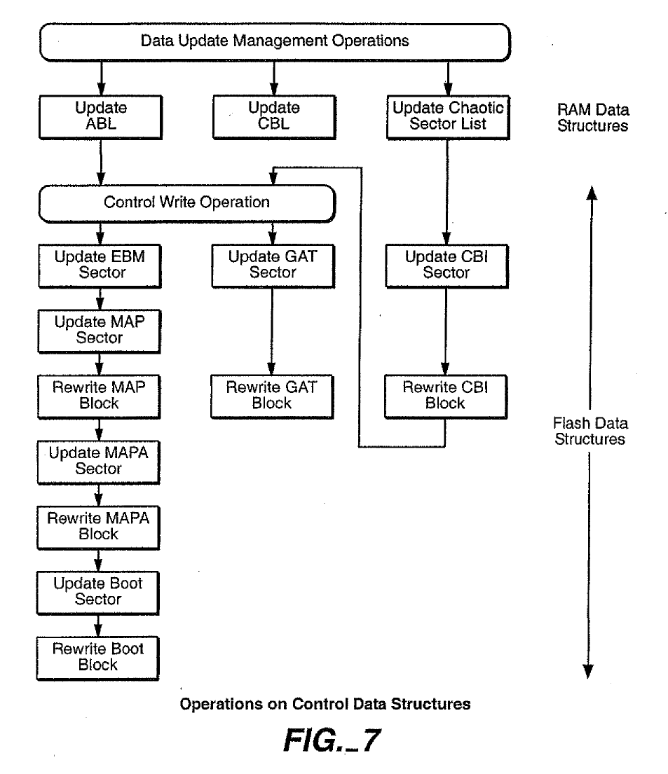

FIG. 7 (adapted from FIG. 20 of U.S. patent application Ser. No. 10/750,155, where it is developed further) illustrates the hierarchy of the operations performed on control data structures shown in FIG. 6 during the course of the operation of the memory management. Data Update Management Operations act on the various lists that reside in RAM. Control data write (or “control write”) operations act on the various control data sectors and dedicated blocks in flash memory and also exchange data with the lists in RAM.

Data update management operations are performed in RAM on the ABL, the CBL and the chaotic sector list. The ABL is updated when an erased block is allocated as an update block or a control block, or when an update block is closed. The CBL is updated when a control block is erased or when an entry for a closed update block is written to the GAT. The update chaotic sector list is updated when a sector is written to a chaotic update block.

A control write operation causes information from control data structures in RAM to be written to control data structures in flash memory, with consequent update of other supporting control data structures in flash memory and RAM, if necessary. It is triggered either when the ABL contains no further entries for erased blocks to be allocated as update blocks, or when the CBI block is rewritten.

In the preferred embodiment, the ABL fill operation, the CBL empty operation and the EBM sector update operation are performed during every control write operation. When the MAP block containing the EBM sector becomes full, valid EBM and MAP sectors are copied to an allocated erased block, and the previous MAP block is erased.

One GAT sector is written, and the Closed Update Block List is modified accordingly, during every control write operation. When a GAT block becomes full, a GAT rewrite operation is performed.

A CBI sector is written, as described earlier, after certain chaotic sector write operations. When the CBI block becomes full, valid CBI sectors are copied to an allocated erased block, and the previous CBI block is erased.

A MAP exchange operation is performed when there are no further erased block entries in the EBB list in the EBM sector.

A MAP Address (MAPA) sector, which records the current address of the MAP block, is written in a dedicated MAPA block on each occasion the MAP block is rewritten. When the MAPA block becomes full, the valid MAPA sector is copied to an allocated erased block, and the previous MAPA block is erased.

A Boot sector is written in a current Boot block on each occasion the MAPA block is rewritten. When the boot block becomes full, the valid Boot sector is copied from the current version of the Boot block to the backup version, which then becomes the current version. The previous current version is erased and becomes the backup version, and the valid Boot sector is written back to it.

The Boot Block (BB) is a special block containing a unique identification code in the header of its first sector, which is located within the memory by the controller by a scanning process during the initialization of the system. The Boot Block contains the necessary information about the system configuration, and pointers to the MAPA block within the flash memory. It also contains information that is returned to a host device in response to interrogation within the host interface protocols. Information is contained in different sector types in the boot block, wherein only the last occurrence of a specific sector type is valid. Typically, two identical copies of the Boot Block are set up for security.

The present invention moves some or all of the control data to the alternate non-volatile memory 150 (FIGS. 2-4), in an arrangement such as that shown in FIG. 5. This allows the management of the memory 200 to be optimized to exploit the characteristics of flash memories for bulk storage of host data, namely by the storing logically contiguous sectors of host data into large block structures having a large erase granularity, while maintain control data for the management of this user data in a non-volatile RAM (NVRAM) formed from an alternate non-volatile technology in memory 150. The NVRAM 150 can then be optimized for its management function, such as choosing a technology that has a finer grained structure (such as allowing erase and/or rewrite on the bit or byte level) so that the most current control data can be maintain non-volatilely on the controller 100 as well for the greater access speed provided by some of the alternate technologies.

For the particular management of exemplary embodiment, as discussed with respect to FIGS. 6 and 7, some or all of the relatively static directory and system control data formerly stored in flash memory 200 can be moved to the NVRAM 150, such as the erased block lists and the bitmap (MAP) listing the erased status of all metablocks in the flash memory. As much of the control data in this hierarchical structure consists of pointers, depending on how large a NVRAM 150 is used, where the pointer can be stored or the actual contents that are pointed to can be stored. For example, the NVRAM could just keep a pointer to the boot block, or if the content of the boot block is not much bigger, the boot block contents themselves can be maintained in the NVRAM; and if the boot block contains pointers, that material can be kept in the NVRAM, and so on until the amount of material becomes too big to exploit the relative advantage of the alternate non-volatile technology used for the NVRAM.

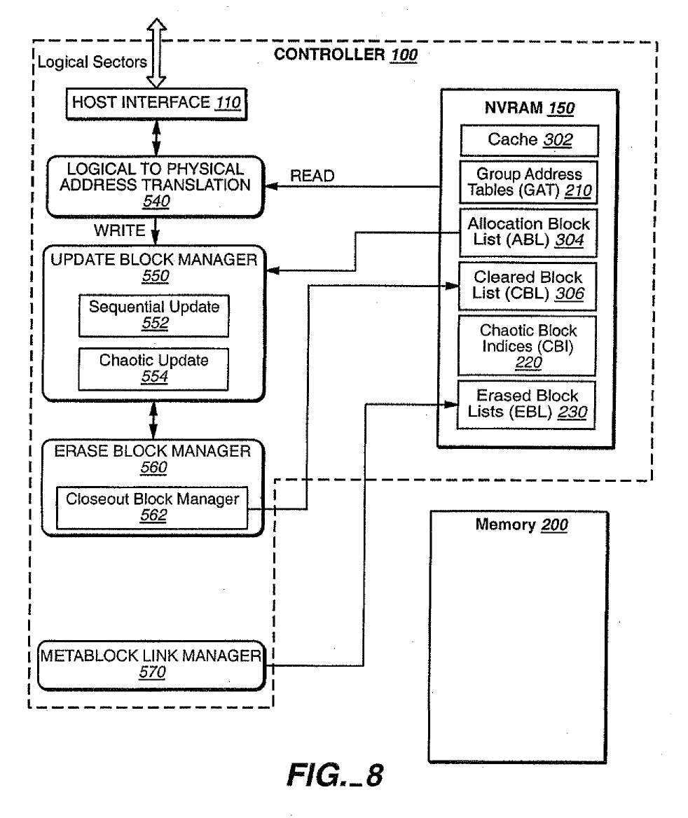

FIG. 8 is a schematic block diagram of the metablock management system as implemented in the controller and flash memory in an exemplary embodiment of the present invention. In terms of function, FIG. 8 corresponds to metablock management system as previously implemented as shown in FIG. 6, except that many of the elements previously stored in memory 200 have been moved to NVRAM 150 and other elements have been consequently eliminated. Consequently, in this arrangement, the elements of FIG. 7 have been either moved in NVRAM 150 or eliminated. For example, Control Data Exchange 580 has been removed as the control information is now contained in NVRAM 150 and no longer needs to be maintained and updated in memory 200. Also, Initialization 590 is also gone as the control information is already present at power up, providing instant on capability. Much of the control data hierarchy, such as MAP 240, can also be removed as these structures point to other data that is now directly maintained in its current form in the NVRAM 150.

Although memory 200 is shown blank, FIG. 8 shows only the metablock management structure. Memory 200 will still contain host data and, according to embodiment as described below, varying amounts of system data. Although the NVRAM 150 is dedicated to the controller 100, as indicated by the broken line in FIG. 8, it may be arranged as in any of FIGS. 2-4. For example, all of the elements may be formed on a single chip or NVRAM 150 may be on a separate chip connected to the controller by a dedicated bus structure.

In practice, a number of practical considerations, such as cost or space availability, may restrict the size of NVRAM 150, in which case only part of the system control data will be maintained on NVRAM 150, rather than the sort of more complete transfer shown in FIGS. 5 and 8. The decision then becomes a cost-benefit analysis based on factors such as increase in access speed, reliability, and endurance, decrease in initialization time and flash memory overhead, and simplification and reduction of firmware code. A set of examples is again based on the structures of U.S. patent application Ser. No. 10/750,155.

A first example is the content formerly maintained in the Chaotic Block Index (CBI) block. Storing all chaotic block information in NVRAM would result in significant gains for some access times, reduce initialization by a dozen or more flash memory reads, simplify power loss recovery, free up a flash metablock, and very significantly simplify the firmware code; however, it could also require several kilobytes of NVRAM. An alternate could be to only store pointer to the most recently written CBI sector, as this would only take a couple of bytes of NVRAM while still noticeable reducing firmware code and shortening initialization time by up to a dozen flash reads.

For the Group Access Table (GAT), maintaining all of the block linking information in NVRAM would noticeably increase some access times, simplify power loss recovery, free up one or more flash metablocks, and very significantly simplify the firmware code. As this would use several tens of kilobytes, this technique is preferred only when a relatively large NVRAM is used, the GAT otherwise being maintained in the memory 200. The alternative of only storing pointers to the most recently written temporary GAT, which would only need a handful of bytes in NVRAM, provides relatively little advantage. Under these circumstances, unless a large NVRAM is used, the NVRAM may be better utilized for some of the described uses.

The situation for the Block Linkage Management block is similar to that of the Group Access Table, resulting in similarly advantages for storing all block linking management data in NVRAM, but again requiring several tens of kilobytes. Storing the pointer to the most recently written sector in this case, however, requires only a couple of bytes and can reduces initialization times by around ten non-sequential reads of memory 200. Similarly, storing sequential update block information, such as start length and address, would reduce initialization times and access time for random reads by around ten reads of memory 200 per update block, as well as simplifying power loss recovery and noticeably simplifying firmware code.

One particularly effective use of a small amount of non-volatile RAM for storing control data is for on the hierarchical structure based on the Boot Block, MAPA block, and Erase Management Block (EBM). As noted above, the boot block contains pointers the MAPA block, which itself contains pointer to the latest EBM block. Consequently, by storing the pointer to the latest EBM sector in the NVRAM 150, as well any other information stored in the boot block, initialization time is reduced by a few dozen non-sequential reads of flash memory 200. Further, this will free up three metablocks in flash memory, with a corresponding increase in the reliability of memory 200, and significantly simply the firmware code. This would require only around four bytes of NVRAM for the controller. The inclusion of EBM data itself would free up another metablock of flash memory, but would need perhaps several hundred more bytes of NVRAM.

Therefore, even with very small NVRAM available with size from 4 bytes it is possible to simplify greatly the firmware code, significantly reduce control data overhead, initialization time and access time. Larger NVRAM memory, from 50 to 100K bytes allows improving further performance, reliability and greatly simplifying the code, which leads to easier implementation and maintenance. As a specific embodiment, the NVRAM 150 could be taken large enough to store pointers to the latest EBM sector, latest block linkage management sector, latest written CBI sector, sequential block information, and firmware (which is consequently significantly simplified and reduced in size), while keeping the GAT information and the actual contents of the EBM, CBI, and block linkage management blocks in flash memory 200.

Concerning the storage of firmware, the controller code can be kept in NVRAM and either executed directly from the NVRAM or uploaded to the controller RAM for execution. The boot code can also be kept in the NVRAM, allowing the use of one controller that easily supports boot when the memory is changed as the appropriate portions of the boot code can be rewritten. To reduce the amount of NVRAM devoted to firmware storage, the firmware code for booting the system can be stored in NVRAM, while the rest of the firmware need not be kept in NVRAM. The boot code would be specific to the type of flash memory, and would control the loading of the remainder of the code from flash to volatile memory for execution. The NVRAM is taking the place of ROM for this purpose in current controllers.

Other examples of program code and data storage that can be maintained in the NVRAM also include code and data for the applications run by the memory system. In this case the memory system can provide other functions to the user, for example it could be a combination of digital photo camera and memory storage system, where the application does not need initialization at power up. Storage could also be provided for code and data for the applications run by the host. In this case, the NVRAM provides additional memory to the host application, e.g. PDAs.)

Another example of storing control data in the NVRAM is to store overhead data for each sector of the memory, and thereby eliminating the sector overhead area in flash. In the current NAND flash memories, it is common for every page have 512+16 bytes, where the 16 bytes are used for control and ECC. To reduce the NAND cost and have a NAND flash without the extra 16 bytes, this overhead can be kept in the NVRAM as part of the system's configuration.

Even if the header information is kept in the memory according to the more traditional arrangement, an NVRAM table can be used to record modifications to flash sector headers, such as providing support for flag overwrites. Some memory types support limited flag overwrite in the Header area. For those that do not, or situations where the space in the header for the necessary redundancy is not available, a table of header overwrites in the alternate non-volatile memory could handle these cases without a significant increase in operating times, thereby improving on the latencies from which a conventional flash-based table suffers.

### Non-Volatile Read/Write Cache Example

The previous section considered an example where the alternate non-volatile memory is used to store control data, and in particular where only a relatively small amount of alternated non-volatile memory is needed. The present section develops exemplary embodiments where the alternate non-volatile memory is large enough to serve as a cache where, for example, data can safely be staged prior to its being written to the to the memory or read back to the host.

One use of NVRAM as a cache is to shadow volatile memory in the controller, to which the volatile RAM can be flushed by writing to NVRAM if, for example, a power-down occurs. Some write cache designs use a buffer containing unwritten host command data at most times, until there is a request to flush this information to memory. This time to flush can be extensive and may interfere with overall performance if the flush requests are not restricted to true power down times; for example, in the case of a camera with a flush command issued after each picture is captured, or whenever the camera wants the card to sleep. One embodiment would always have cache data in the NVRAM as the transfer buffer itself. An alternate embodiment requiring a smaller non-volatile cache however could copy the cache tables and cache memory to the NVRAM each time a flush command is received. When the card powers up, the cache data is restored along with the tables and operation proceeds as normal. The advantage of this approach is that it can avoid unnecessary (and time wasting) writes to flash since hits to the data cache area invalidate that write data, thereby allowing that write to be skipped or let it be grouped with other writes which can be handled together.

As a more detailed example, the non-volatile cache can be used as a non-volatile staging area to allow fast programming of the flash memory 200 without the use of meta-blocks or other logical structures introduced to increase access parallelism. The use of meta-blocks to increase parallelism in non-volatile memories, and in flash memories in particular, are described in U.S. patent application Ser. Nos. 10/750,155, 10/749,189, and 10/750,157, all incorporated by reference, above. According to another aspect of the present invention, a non-volatile cache is used to increase programming parallelism without the use of composite logical structures such as meta-blocks.

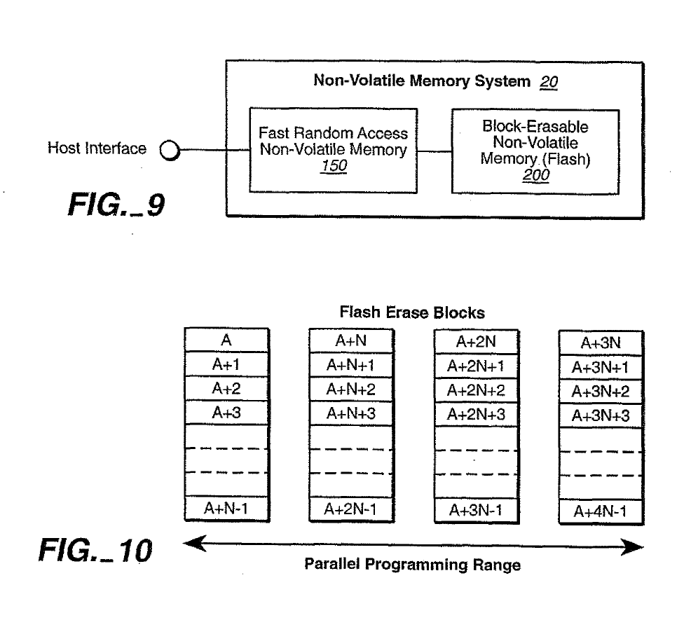

FIG. 9 is block diagram schematically representing the use of a hybrid non-volatile system according to this embodiment. The memory system 20 includes a first non-volatile memory 150 connected to exchange data with the host through the host interface on one side and exchange data with the memory 200 on the other side. The other elements of the memory system are suppressed to simplify the discussion and the two non-volatile memories can be arranged as in any of FIGS. 2-4. In the exemplary embodiment, the memory 200 is taken to be a block-erasable non-volatile memory, such as a flash memory, and the NVRAM 150 is a fast random access non-volatile memory, such as FeRAM, that is a cache for the memory.

The fast random-access NVM 150 is used to accumulate sectors written by a host. The sectors will be sent by the host in sequential logical order for a given data stream. The controller manages the flash memory 200 as individual minimum-sized erase blocks, which are not linked into meta-blocks. The sectors of host data are transferred from NVM to flash memory in non-sequential logical order, to allow pages from different erase blocks to be programmed in parallel. Under this arrangement, the amount of data to be relocated during data relocation operations, or “garbage collection”, of fragmented blocks is much less than when meta-blocks are used.

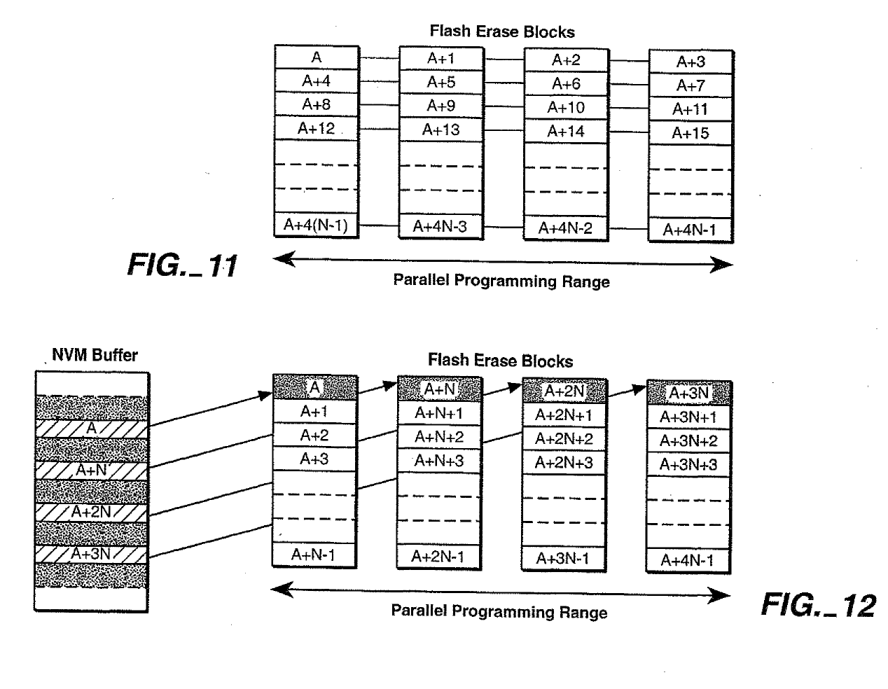

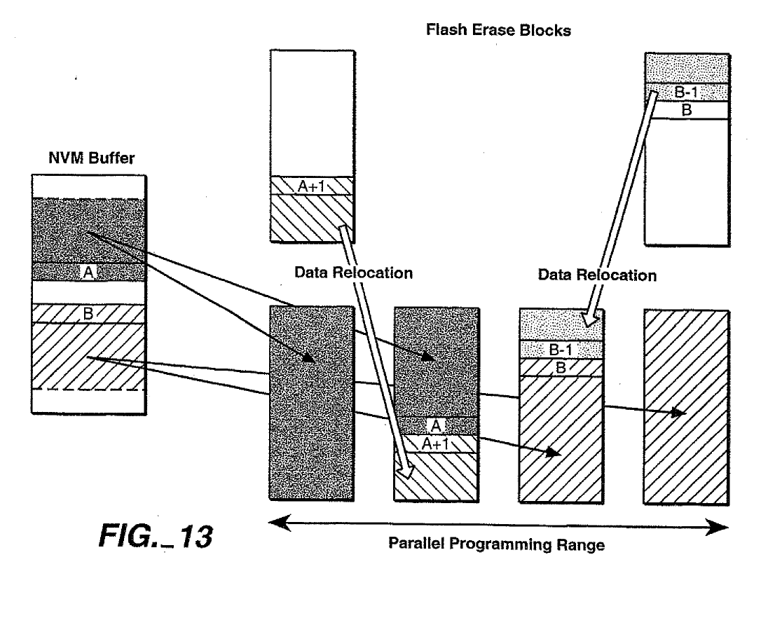

FIG. 10 is a schematic representation of the logical to physical mapping of sectors under this arrangement. A first minimum-sized erase block stores a set of N contiguous logical sectors from logical address A. Other minimum-sized erase blocks in different planes of the memory 200 store subsequent sets of sectors from logical addresses A+N, A+2N, and A+3N. The exemplary embodiment allows for the parallel programming of up to four pages into four semi-autonomous sub-arrays or “planes”. The planes can be on the same die or distributed across several chips. Sectors A, A+N, A+2N, and A+3N, which are in different eras blocks and different planes of the memory, may be programmed in parallel. For comparison, a standard prior art arrangement of erase blocks into the composite logical structures of meta-blocks normally used for the parallel programming of sub-arrays is illustrated with respect to FIG. 11.

In the prior art, when multiple planes are written in parallel, once enough data from the host is cached to write across the range of parallel programming, the data is written. This is done by forming the physical erase blocks of the memory into composite logical structures know as meta-blocks (or sometimes super-blocks), an arrangement shown in FIG. 11. The arrangement of FIG. 11 shows four blocks per meta-block. Individual blocks within separate planes of the memory are selected to be linked into meta-blocks, according to a block linking algorithm (see U.S. patent application Ser. Nos. 10/750,155, 10/749,189, and 10/750,157.) As shown, for the four-plane linking, equivalent sectors (A+n) to (A+n+3) within the linked blocks are linked for each n=0 to n=(N−1). Under this arrangement, for a given n the system only needs to accumulate sectors (A+n) to (A+n+3), rather than all 4N sectors, before they can be written in parallel to the flash memory.

Normally, a system would end up with the sort of order shown in FIG. 10 if there was no writing in parallel and the blocks were written in the order received in a single plane until it were filled, and then moving on to the next plane and repeating the process. In order to be able to read and write more than one plane at the same time, the meta-block arrangement of FIG. 11 is used since the system can write as soon as it has received four (or whatever the range of parallelism is) sectors of data. Under the arrangement of FIG. 10, to write the planes in parallel without the use of meta-blocks, the system needs to accumulate at least A+3N sectors of data before it can begin writing. With a normal, volatile cache, this would be risky as the accumulated data is not secure until transferred out to the flash memory.

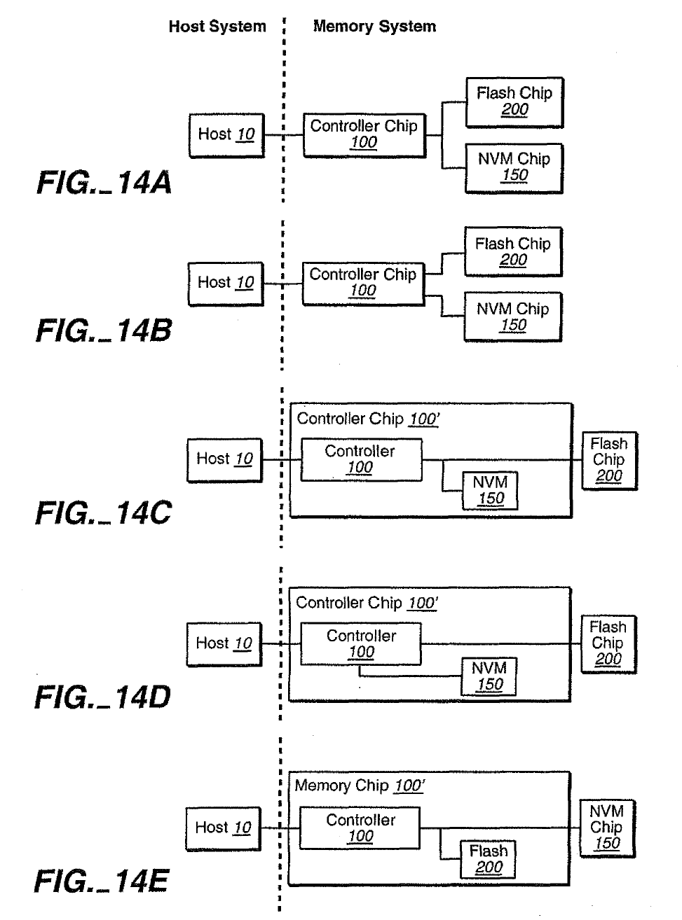

As shown in FIG. 10, each logical block of sectors is mapped to a single erase block. The sectors follow sequential logical ordering within a single erase block, where no interleaving of sequential sectors amongst different erase blocks is performed. The introduction of such a large non-volatile cache goes beyond being just a qualitative difference and becomes quantitative as it now allows the implementation of the techniques of FIGS. 10 and 12: it is based on a large (to hold enough data), secure (hence non-volatile), fast (so not flash) cache.

The sequential sector programming sequence is illustrated in FIG. 12. Sequential logical sectors for a given stream of data from a host are accumulated in the NVM buffer. Once sufficient data is accumulated to fully program a maximum set of erase blocks within the parallel programming range of the system (here 3N+1 sectors to begin), non-sequential logical sectors to be stored in corresponding pages of a set of separate erase blocks are transferred from the non-volatile cache to the flash memory. Thus, even without the introduction of meta-blocks, erase blocks in the set are programmed in parallel, maintaining maximum programming bandwidth in flash memory.

In the sequence of FIG. 12, the host may fail to write sufficient sectors to the NVM buffer to allow programming across the full parallel programming range of the system. For example, the write stream may end, and no further data may be written by the host. In this case, data accumulated in the NVM buffer may be programmed in parallel to a lesser number of erase blocks. This allows the data to be mapped more efficiently to flash memory blocks, with fewer sectors that were not updated by the host having to be relocated from one block to another in flash memory, than would be the case if metablocks were used.

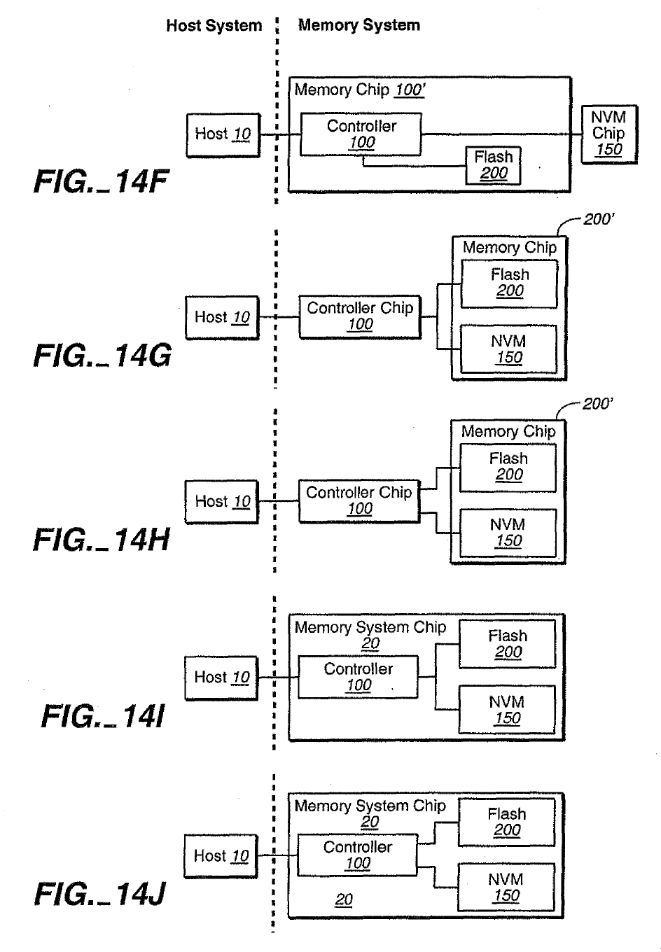

The end of a logically sequential stream of sectors, here ending at sector A, and the beginning of an unrelated logically sequential stream of sectors, beginning at B, that are both present in the NVM buffer, may be stored together in a set of flash erase blocks, as illustrated in FIG. 13. Sectors which must be relocated to the set of erase blocks, such as those following sector A that start with sector A+1 and those that precede sector B and end at B−1, to allow garbage collection of the original block locations of the data may be read and stored in the NVM buffer. The sectors from multiple host streams and as well as the sectors read from multiple original block locations, which are present in the NVM buffer, may then be programmed in parallel to the blocks in the set, maintaining maximum programming bandwidth in flash memory. Under this arrangement, the maximum amount of data that must be relocated during garbage collection is a fraction of a single erase block.

When compared to meta-block based implementations, the flash memory programming bandwidth for long streams of logically sequential data according to the present invention is the same as would be achieved with use of metablocks. The flash memory programming bandwidth for multiple short streams of logically sequential data is higher than would be achieved with use of metablocks. This is as a result of the reduced amount of data relocation to complete blocks containing the start and end of streams. Such short streams exist when multiple short unrelated files are being written, or when the logical address space of the drive is very fragmented. Another advantage of the present invention is that by maintaining a relatively large amount of data in the fast non-volatile cache, the probability of a cache hit is proportional increased; this will also reduce the amount of incurred garbage collection since the has not yet been committed to the flash memory. Additionally, by dispensing with meta-blocks, the attendant management overhead needed for meta-blocks is also eliminated.

### Further Extensions

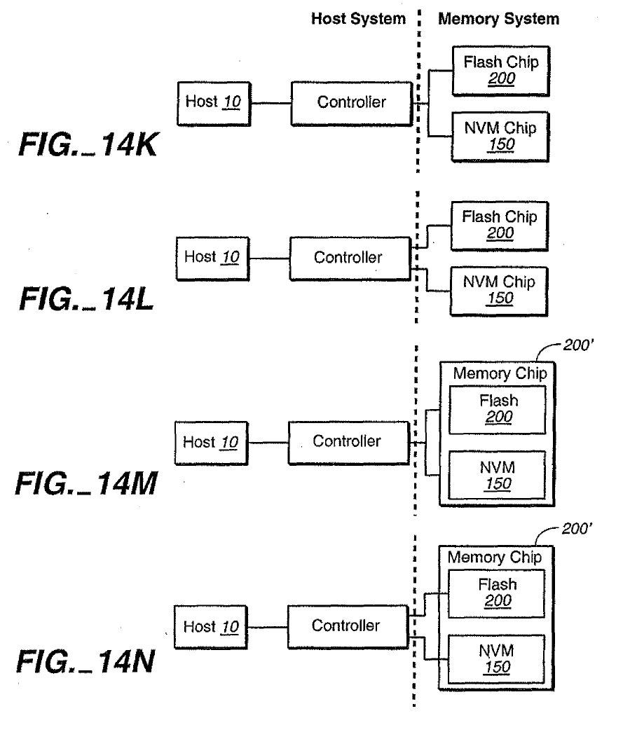

As noted above, the various aspects of the present invention can be implemented in a number of topologies, where some of the exemplary embodiments are shown in FIGS. 2-4. More generally, the physical elements of the exemplary embodiments of the present invention consist of the memory system of the first non-volatile technology 200, taken as a Flash memory in the discussion, the alternate non-volatile memory 150, and the controller 100. The two memories 150 and 200 can be connected to the controller 100 by separated busses or using a shared bus structure. The controller 100 is then connected, or connectable, to a host 10. These three elements of the memory system can all be formed on individual chips, or one or more can be formed on a common substrate. A number of examples are shown in FIGS. 14 A-J.

Most of the exemplary embodiments discussed above are for memory cards, where the controller 100 and memories 150 and 200 are part of a detachable integrated circuit card. More generally, the controller, and also either or both the memories, may be embedded in the host 10. When the controller is part of the host system, it can implement as hardware controller, software, firmware, or a combination of these. Further, the controller functions can be distributed between the host and an on-chip controller.

Particular sets of alternate embodiments discussed above are those, such as the xD or MemoryStick cards, where the card lacks a full controller. FIGS. 14K-N show several partitions of the memory system in this case. The controller, again implemented as hardware controller, software, firmware, or a combination of these, now forms part of the host system, with the first non-volatile memory (here indicated as flash) and the alternate NVM together on the memory card. These two memories may be formed on distinct chips or share a chip, and have distinct busses or a common bus structure.

In any of these arrangements, the memory system can be a card that is detachably connectable to a host. In other embodiments, the components are embedded and soldered to the host motherboard, either with a hardware controller or with control functions performed by host software/firmware. The memory system can also provided on a card/module, typically including a controller chip, but the card/module is then soldered to the host motherboard, saving the cost of a connector as it is not user removable. In other variations, the host itself is also on a memory card along with the memory system. An example could be where a processor on a card receives information from a system to which it is connected, and performs some sort of processing on the information to generate completely different data files for storage in the memory system. In this case, the on-card processor is the host.

Although the exemplary embodiments of the present invention have been based on the use of a flash EEPROM technology for the memory 200, other technologies may also be employed. Similarly, although reference has been made to FeRAM for the alternate non-volatile memory 150, other non-technologies, including MRAM, Ovonics, non-flash EEPROM, may also be employed for their relative advantages. Other technologies include, but are not limited to, sub 0.1 urn transistors, single electron transistors, organic/carbon based nano-transistors, molecular transistors, Polymer Ferroelectric RAM (PFRAM); Micro Mechanical Memories; Capacitor-less SOI Memories; Nitride Storage Memories; and other technologies being developed. For example, NROM and MNOS cells, such as those respectively described in U.S. Pat. No. 5,768,192 of Eitan and U.S. Pat. No. 4,630,086 of Sato et al., or magnetic RAM and FRAM cells, such as those respectively described in U.S. Pat. No. 5,991,193 of Gallagher et al. and U.S. Pat. No. 5,892,706 of Shimizu et al., all of which are hereby incorporated herein by this reference, could also be used.

Although specific examples of various aspects of the present invention have been described, it is understood that the present invention is entitled to protection within the scope of the appended claims.

It is claimed:

1. A method, comprising:
operating a non-volatile memory system, the non-volatile memory system including a controller integrated circuit chip, one or more first integrated circuit chips each having one or more flash memory arrays formed of EEPROM based memory cells with a NAND-type architecture, and at least one second integrated circuit chip having a non-volatile random access memory of a type other than an EEPROM based flash memory, the operating of the volatile memory system including storage of data received from a host connected thereto in a process including:
receiving from the host at the controller a stream of a first plurality of sectors of data having sequential logical addresses;
caching in the non-volatile random access memory by the controller of the first plurality of sectors having sequential logical addresses as received from the host;
forming by the controller of sectors of data cached in the non-volatile random access memory, including sectors of the first plurality of sectors having sequential logical addresses, into composite N page structures, where each of the pages includes one or more sectors and N is an integer greater than one;
transferring the composite structures to one or more of the first integrated circuit chips; and
writing the composite structures into N arrays on the first integrated circuit chips, wherein when writing the composite structures in the N arrays the N pages of each composite structure are written concurrently in parallel into a corresponding one of the N arrays,
wherein the controller forms the composite structures so that when written into the N arrays, sectors of the first plurality of sectors having sequential logical addresses are written to have sequential physical addresses in a first of the N arrays.

2. The method of claim 1, wherein the second integrated circuit chip is connected to the controller integrated circuit chip along a separate bus than the one or more first integrated circuit chips.

3. The method of claim 2, wherein the controller integrated circuit chip includes a volatile random access memory and where, when forming sectors of data into composite N page structures, the composite structures are stored in the volatile random access memory prior to transferring the composite structures to one or more of the first integrated circuit chips.

4. The method of claim 1, wherein the process further includes:
subsequent to receiving at the controller a stream of the first plurality of sectors having sequential logical addresses from a host, receiving at the controller a stream of a second plurality of sectors having sequential logical addresses from a host; and
caching by the controller in the non-volatile random access memory of the second plurality of sectors having sequential logical addresses as received from the host,
wherein the composite N page structures further include sectors of the second plurality of sectors having sequential logical addresses and
wherein the controller forms the composite structures so that when written into the N arrays, sectors of the second plurality of sectors having sequential logical addresses are written to have sequential physical addresses in a second of the N arrays.

5. The method of claim 1, wherein the process further includes:
prior to receiving at the controller the stream of the first plurality of sectors having sequential logical addresses, writing into the first integrated circuit chips one or more additional sectors having logical addresses that are sequential with the first plurality of sectors having sequential logical addresses,
wherein the composite N page structures further include the additional sectors, and
wherein the controller forms the composite structures so that when written into the N arrays, sectors of the first plurality of sectors having sequential logical addresses and additional sectors are written to have sequential physical addresses in a second of the N arrays.

6. The method of claim 1, wherein the non-volatile random access memory of a type other than an EEPROM based flash memory is ferroelectric random-access memory.

7. The method of claim 1, wherein the non-volatile random access memory of a type other than an EEPROM based flash memory is magnetic random-access memory.

8. The method of claim 1, wherein the non-volatile random access memory of a type other than an EEPROM based flash memory is an ovonic type random-access memory.

9. The method of claim 1, wherein the operating of the non-volatile memory system further includes:
subsequent to receiving from the host at the controller the stream of a first plurality of sectors of data having sequential logical addresses, receiving updated data for more or more the first plurality of sectors from the host; and
replacing the sectors of data for which the updated data was receiving with the updated data in the non-volatile random access memory, wherein the composite N page structures are formed using the updated data.

10. The method of claim 1, wherein the operating of the non-volatile memory system further includes:
maintaining in the non-volatile random access memory by the controller of control information for the management of the data received from the host as written on the first integrated circuit chips.

11. The method of claim 10, wherein said control information includes firmware code.

12. The method of claim 10, wherein said control information includes logical address to physical address conversion data.

13. The method of claim 10, wherein said control information includes data on linking of physical blocks into multiple-block logical structures.

14. The method of claim 10, wherein said control information includes data on erase status of physical blocks.

15. The method of claim 10, wherein said control information includes boot information.

16. The method of claim 10, wherein the memory system does not maintain on the first integrated circuit chips said control information maintained in the non-volatile random access memory by the controller.
